(19) United States
(12) Patent Application Publication
(10) Pub. No.: US 2012/0097527 A1
(43) Pub. Date: Apr. 26, 2012

(54) FILM FORMATION APPARATUS AND FILM FORMING METHOD

(75) Inventors: Shuji Kodaira, Susono-shi (JP); Tomoyuki Yoshihama, Susono-shi (JP); Koukichi Kamada, Susono-shi (JP); Kazumasa Horita, Susono-shi (JP); Junichi Hamaguchi, Susono-shi (JP); Shigeo Nakanishi, Susono-shi (JP); Satoru Toyoda, Susono-shi (JP)

(73) Assignee: ULVAC, INC., Chigasaki-shi (JP)

(21) Appl. No.: 13/381,019

(22) PCT Filed: Jul. 15, 2010
(86) PCT No.: PCT/JP2010/061985

§ 371 Date: Dec. 27, 2011

(30) Foreign Application Priority Data
Jul. 17, 2009 (JP) P2009-169447

(51) Int. Cl. C23C 14/35

(52) U.S. Cl. 204/192.12; 204/298.08

(57) ABSTRACT

A film formation apparatus includes: a chamber in which both a body to be processed and a target are disposed; a first magnetic field generation section generating a magnetic field; and a second magnetic field generation section including a first generation portion to which a current defined as “Iu” is applied and a second generation portion to which a current defined as “Id” is applied, the first generation portion being disposed at a position close to the target, the second generation portion being disposed at a position close to the body to be processed, the second magnetic field generation section applying the currents to the first generation portion and the second generation portion so as to satisfy the relational expression Id<Iu, the second magnetic field generation section allowing perpendicular magnetic lines to pass between the target and the body to be processed.

### BACKGROUND OF THE INVENTION

1. Field of the Invention

The present invention relates to a film formation apparatus and a film forming method which are used for forming a coat on a surface of a body to be processed, and particularly, relates to a film formation apparatus and a film forming method employing a DC magnetron method using a sputtering method which is one of several thin film forming methods.

This application claims priority from Japanese Patent Application No. 2009-169447 filed on Jul. 17, 2009, the contents of which are incorporated herein by reference in their entirety.

2. Background Art

Conventionally, a film formation apparatus using a sputtering method (hereinafter, refer to “sputtering apparatus”) is used in a film formation step in which, for example, a semiconductor device is manufactured.

As a sputtering apparatus of such intended use, with miniaturizing of wiring pattern in recent years, an apparatus is increasingly and strongly required in a coat can be formed over an entire surface of a substrate to be processed with excellent coatability in microscopic holes having a high-aspect ratio such as the ratio of the depth divided by the width exceeding three, that is, improvement of coverage is strongly required.

Generally, in the aforementioned sputtering apparatus, a magnet assembly which is constituted of a plurality of magnets having alternately different polarities is disposed behind, for example, a target (opposite side of a sputtering face of a target).

This magnet assembly generates a tunnel-shaped magnetic field at the anterior target (space to which a sputtering face is exposed), the electron density is improved at the anterior target and the plasma density becomes high as a result of capturing electrons which are ionized at the anterior target and secondary electrons generated by sputtering.

In such sputtering apparatus, the region of the target which is affected according to the above-described magnetic field is preferentially sputtered.

Consequently, in terms of improvement of stability of the electric discharge, efficiency in the use of target, or the like, if the above-described region located near, for example, the center of the target, the amount of erosion in the target increases near the center thereof when sputtering is carried out.

In such case, the target material particles sputtered from the target (e.g., metal particles, hereinafter referred to as “sputtered particles”) are adhered to a peripheral portion of the substrate at an angle which is inclined with respect to a vertical direction of the substrate.

As a result, in the case where the sputtering apparatus is used for the aforementioned film formation step, particularly, it is conventionally known that a problem of asymmetric coverage being formed at the peripheral portion of the substrate.

Particularly, in the cross-sectional face of the microscopic holes formed at the peripheral portion of the substrate, there is a problem in that the shape of a coat formed between the bottom of the microscopic holes and one of the side walls thereof is different from the shape of a coat formed between the bottom of the microscopic holes and the other of the side walls thereof.

In order to solve the foregoing problem, a sputtering apparatus is known in, for example, Japanese Unexamined Patent Application, First Publication No. 2008-47661, the apparatus includes a first sputtering target and a second sputtering target, the first sputtering target is disposed above a stage on which a substrate is mounted in a vacuum chamber and is substantially parallel to the top face of the stage, and the second sputtering target is disposed at obliquely upside of the stage so as to face in a diagonal direction with respect to the top face of the stage, that is, the apparatus provided with a plurality of cathode units.

However, as in disclosure of Japanese Unexamined Patent Application, First Publication No. 2008-47661, when cathode units are disposed inside the vacuum chamber, the constitution of the apparatus becomes complicated, sputtering power sources or magnet assemblies are also necessary in accordance with the number of targets, the number of components increases, there is a problem in that the cost thereof increases. Furthermore, the efficiency in the use of the target deteriorates, and there is a problem in that the cost of manufacturing increases.

### SUMMARY OF THE INVENTION

The invention was made in order to solve the above problems, and has an object to provide a film formation apparatus and a film forming method which form a coat with a high level of coatability in holes, trenches, or microscopic patterns, which have a high-aspect ratio and are formed on the substrate, and it is possible to ensure the same coatability of a peripheral portion of the substrate as that of a center portion of the substrate.

A film formation apparatus of a first aspect of the invention includes: a chamber having an inner space in which both a body to be processed and a target (base material of a coat) are disposed (stored) so that the body to be processed and the target are opposed to each other, the body to be processed having a film formation face, the target having a sputtering face; a pumping section reducing a pressure inside the chamber; a first magnetic field generation section generating a magnetic field in the inner space to which the sputtering face is exposed (anterior to the sputtering face); a direct-current power source applying a negative direct electric current voltage to the target; a gas introduction section introducing a sputter gas into the chamber; and a second magnetic field generation section including a first generation portion to which a current defined as “Iu” is applied and a second generation portion to which a current defined as “Id” is applied, the first generation portion being disposed at a position close to the target (near the target), the second generation portion being disposed at a position close to the body to be processed (near the body to be processed), the second magnetic field generation section applying the currents to the first generation portion and the second generation portion so as to satisfy the relational expression Id<Iu, the second magnetic field generation section generating a perpendicular magnetic field so as to allow perpendicular magnetic lines of force thereof having a predetermined distance to pass between an entire surface of the sputtering face and an entire surface of the film formation face of the body to be processed.

In the film formation apparatus of the first aspect of the invention, it is preferable that the Iu and the Id satisfy the relational expression 1<Iu/Id≦3.

A film forming method of a second aspect of the invention includes: preparing a film formation apparatus, the film formation apparatus including: a chamber having an inner space in which both a body to be processed and a target are disposed so that the body to be processed and the target are opposed to each other, the body to be processed having a film formation face, the target having a sputtering face; a pumping section reducing a pressure inside the chamber; a first magnetic field generation section generating a magnetic field in the inner space to which the sputtering face is exposed; a direct-current power source applying a negative direct electric current voltage to the target; a gas introduction section introducing a sputter gas into the chamber; and a second magnetic field generation section including a first generation portion disposed at a position close to the target and a second generation portion disposed at a position close to the body to be processed, the second magnetic field generation section generating a perpendicular magnetic field so as to allow perpendicular magnetic lines of force thereof having a predetermined distance to pass between an entire surface of the sputtering face and an entire surface of the film formation face of the body to be processed; applying a current defined as “Iu” to the first generation portion; applying a current defined as “Id” to the second generation portion; and controlling the currents which are applied to the first generation portion and the second generation portion so as to satisfy the relational expression Id<Iu.

In the film forming method of the second aspect of the invention, it is preferable that the currents supplied to the first generation portion and the second generation portion be controlled so that the Iu and the Id satisfy the relational expression 1<Iu/Id≦3.

### EFFECTS OF THE INVENTION

According to the invention, since a perpendicular magnetic field is generated so that the perpendicular magnetic field lines pass between the entire surface of the target and the entire surface of the body to be processed, the directions of the sputtered particles which have positive electrical charge and are scattered from the sputtering face of the target by sputtering are changed due to the above-described perpendicular magnetic field.

Because of this, the sputtered particles are substantially perpendicularly directed to the body to be processed and adhered thereto.

As a result, it is possible to form a coat with a high level of coatability in the holes, the trenches, or the microscopic patterns, which have a high-aspect ratio, by use of the film formation apparatus of the invention in a film formation step for manufacturing the semiconductor device.

Furthermore, it is possible to form a coat on a peripheral portion of the body to be processed with the same coatability as the coatability of a center portion of the body to be processed.

Additionally, the problem in that asymmetric coverage is formed on the peripheral portion of the processed body is solved.

Particularly, the problem is solved in that the shape of the coat formed between the bottom of the microscopic holes and one of the side walls thereof is different from the shape of the coat formed between the bottom of the microscopic holes and the other of the side walls thereof in the cross-sectional face of the microscopic holes formed at the peripheral portion of the substrate.

In the second magnetic field generation section of the invention, in a case where the value of the current (first electrical current) which is applied to the first generation portion disposed at the position close to the target is defined as Iu, and where the value of the current (second electrical current) which is applied to the second generation portion disposed at the position close to the body to be processed is defined as Id, the currents are applied to the second magnetic field generation section so as to satisfy the relational expression Id<Iu.

For this reason, the magnetic flux density at the position close to the target is greater than the magnetic flux density at the position close to the body to be processed, and the sputtered particles which are scattered in the position close to the target are effectively induced toward the body to be processed.

As a result, it is possible to form a coat with a high level of coatability in the holes, the trenches, or the microscopic patterns, which have a high-aspect ratio and are formed on the substrate.

### BRIEF DESCRIPTION OF THE DRAWINGS

FIG. 1 is a cross-sectional view schematically showing the structure of a film formation apparatus related to the invention.

FIG. 2A is a diagram showing a state where a perpendicular magnetic field is generated in the film formation apparatus related to the invention.

FIG. 2B is a diagram showing a state where a perpendicular magnetic field is generated in the film formation apparatus related to the invention.

FIG. 3 is a cross-sectional view schematically showing the structure of a microscopic hole and a trench having a high-aspect ratio, which are formed on a substrate.

FIG. 4 is a figure showing a relationship between the values of currents supplied to each of an upper coil and a lower coil, and the evaluation results of coatability of a coat formed on a side wall.

FIG. 5 is a figure showing a relationship between the values of currents supplied to each of an upper coil and a lower coil, and the evaluation results of minimum opening of a microscopic hole.

### DESCRIPTION OF THE PREFERRED EMBODIMENTS

Hereinafter, an embodiment of a film formation apparatus and a film forming method which are related to the invention will be described with reference to drawings.

Additionally, in order to make the respective components be of understandable size in the drawing, the dimensions and the proportions of the respective components are modified as needed compared with the real components in the respective drawings used in explanation described below.

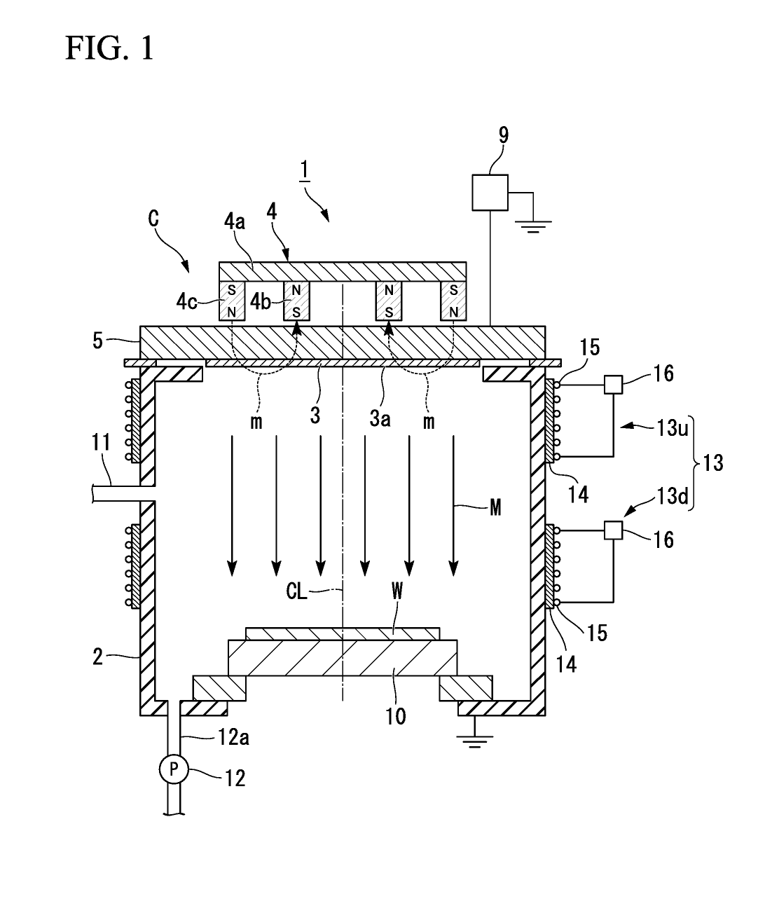

As shown in FIG. 1, a film formation apparatus 1 is a film formation apparatus using a DC magnetron sputtering method and is provided with a vacuum chamber 2 (chamber) capable of generating a vacuum atmosphere.

A cathode unit C is attached to a ceiling portion of the vacuum chamber 2.

Moreover, in the explanation described below, the position close to the ceiling portion of the vacuum chamber 2 is referred to as “upper” and the position close to the bottom portion of the vacuum chamber 2 is referred to as “lower”.

The cathode unit C is provided with a target 3, and the target 3 is attached to a holder 5.

Furthermore, the cathode unit C provided with a first magnetic field generation section 4 generating a tunnel-shaped magnetic field in a space (anterior to sputtering face 3a ) to which a sputtering face (lower face) 3a of the target 3 is exposed.

The target 3 is made of a material, for example, Cu, Ti, Al, or Ta, which is appropriately selected in accordance with the composition of the thin film which is to be formed on a substrate W to be processed (body to be processed).

The target 3 is formed in a predetermined shape (e.g., a circular form in a plan view) using a known method so that the shape thereof corresponds to the shape of the substrate W to be processed and so that the surface area of the sputtering face 3a is greater than the surface area of the substrate W.

Additionally, the target 3 is electrically connected to a DC power source 9 (sputtering power source, direct-current power source) having a known structure, and a predetermined negative electrical potential is applied to the target 3.

The first magnetic field generation section 4 is disposed at the position of the holder 5 (upper side, back side of the target 3 or holder 5) opposite to the position at which the target 3 (sputtering face 3a ) is disposed.

The first magnetic field generation section 4 is constituted of a yoke 4a disposed in parallel with the target 3 and magnets 4b and 4c provided at a lower face of the yoke 4a.

The magnets 4b and 4c are arranged so that polarities of leading ends of magnets 4b and 4c arranged at the position close to the target 3 are alternately different from each other.

The shape or the number of the magnets 4b and 4c is appropriately determined in accordance with the magnetic field (shape or profile of magnetic field) formed in the space (anterior to the target 3) to which the sputtering face 3a is exposed in terms of improvement of stability of the electric discharge, efficiency in the use of target, or the like.

As a shape of the magnets 4b and 4c, for example, a lamellate shape, a rod shape, or a shape to which such shapes are appropriately combined may be employed.

Moreover, a transfer mechanism may be provided at the first magnetic field generation section 4, the first magnetic field generation section 4 may be reciprocally moved or rotated at the back face side of the target 3 by the transfer mechanism.

A stage 10 is disposed at the bottom of the vacuum chamber 2 so as to face the target 3.

The substrate W is mounted on the stage 10, the position of the substrate W is determined by the stage 10, and the substrate W is maintained.

Furthermore, one end of a gas pipe 11 (gas introduction section) introducing a sputter gas such as argon gas or the like thereinto is connected to a side wall of the vacuum chamber 2, and the other end of the gas pipe 11 is communicated with a gas source with a mass-flow controller (not shown in the figure) interposed therebetween.

Additionally, an exhaust pipe 12a which is communicated with a vacuum pumping section 12 (pumping section) is connected to the vacuum chamber 2, and the vacuum pumping section 12 is constituted of a turbo-molecular pump, a rotary pump, or the like.

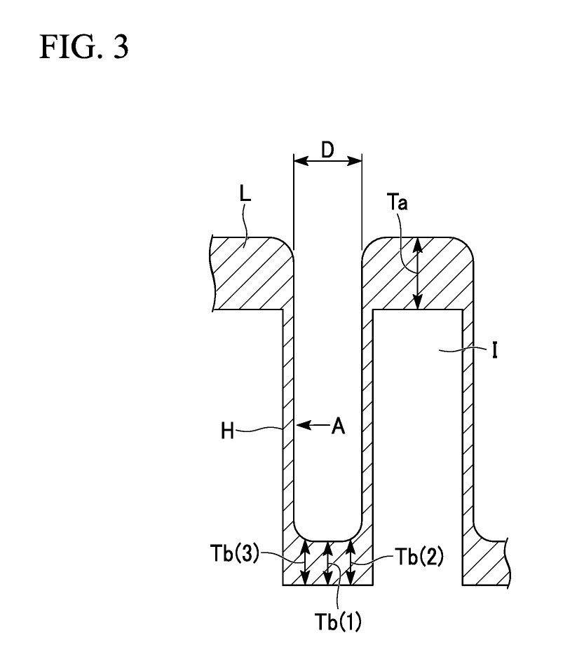

FIG. 3 partially shows a substrate on which a coat is formed by use of the film formation apparatus 1 and is a cross-sectional view schematically showing the structure of a microscopic hole and a trench having a high-aspect ratio which are formed on a substrate.

In FIG. 3, reference numeral H indicates a microscopic hole having a high-aspect ratio, and reference numeral L indicates a thin film formed on the substrate.

In the substrate W to be subjected to a film formation processing, a microscopic hole H having a high-aspect ratio is formed in this silicon oxide film by patterning after a silicon oxide film (insulating film) I is formed on the top face of a Si wafer.

However, in a conventional film forming method, when the target 3 is sputtered, the region of the target 3 which is affected according to the magnetic field generated by the first magnetic field generation section 4 is preferentially sputtered, and target material particles that are target material particles are scattered due to this sputtering.

In this case, erosion is generated at the region in the target which is affected according to the magnetic field as described above.

Additionally, the sputtered particles which are filed from the target are incident to a peripheral portion of the substrate W at an angle which is inclined with respect to the direction vertical to the substrate W, and are adhered to the substrate W.

When a thin film L such as a barrier layer made of Ti or Ta, a seed layer made of Al or Cu, or the like is formed on the substrate W by sputtering target 3 using such conventional film forming method, there is a problem in that asymmetric coverage is formed in the microscopic holes which are located at the peripheral portion of the substrate W.

Particularly, due to the sputtered particles being adhered to the peripheral portion of the substrate W at the angle which is inclined with respect to the direction vertical to the substrate W, the shape of the coat formed between the bottom of the microscopic holes and one of the side walls thereof is different from the shape of the coat formed between the bottom of the microscopic holes and the other of the side walls thereof in the cross-sectional face of the microscopic holes formed at the peripheral portion of the substrate.

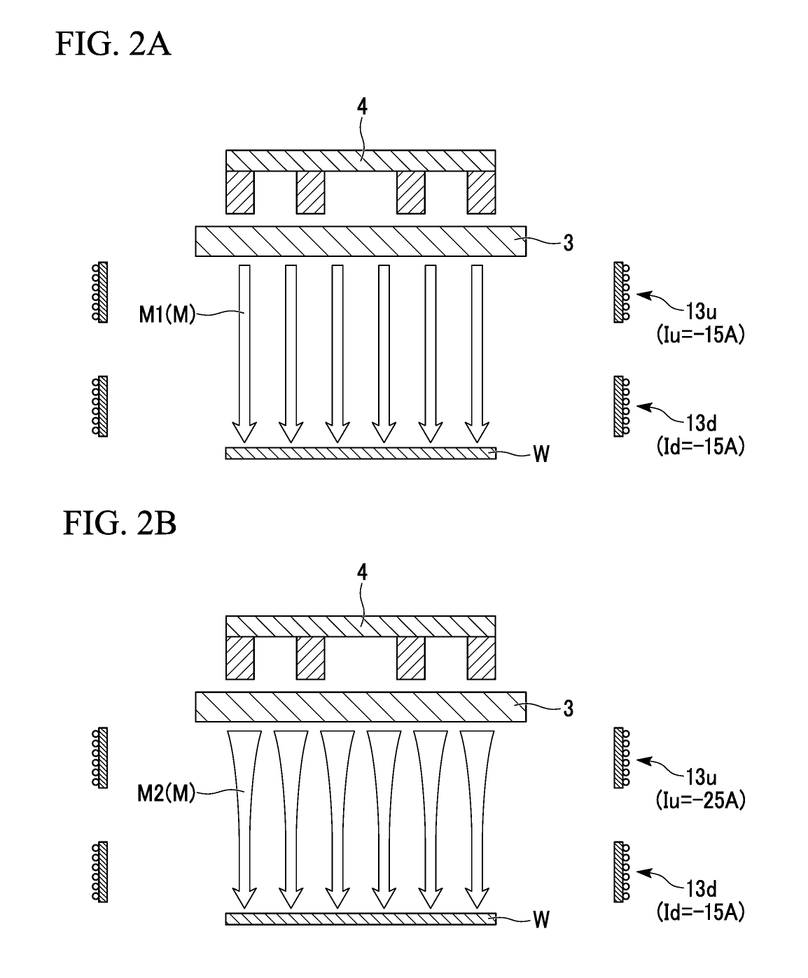

In contrast, a second magnetic field generation section 13 is provided in the film formation apparatus 1 of the embodiment, and the second magnetic field generation section 13 generates perpendicular magnetic field lines M between the entire surface of the sputtering face 3a of the target 3 and the entire surface of the substrate W as shown in FIG. 2A.

The second magnetic field generation section 13 includes an upper coil 13u (first generation portion) disposed at the position close to the target 3 and a lower coil 13d (second generation portion) disposed at the position close to the substrate W.

The upper coil 13u and the lower coil 13d are provided at external walls of the vacuum chamber 2 and around the reference axis CL connecting between the centers of the target 3 and the substrate W.

The upper coil 13u and the lower coil 13d are arranged separately from each other at a predetermined distance in the vertical direction of the vacuum chamber 2.

The upper coil 13u includes a ring-shaped coil support member 14 which is provided at the external walls of the vacuum chamber 2, and the upper coil 13u is configured by winding a conductive wire 15 on the coil support member 14.

Furthermore, a power supply device 16 supplying electrical power to the upper coil 13u (energization) is connected to the upper coil 13u.

The lower coil 13d includes a ring-shaped coil support member 14 which is provided at the external walls of the vacuum chamber 2, and the lower coil 13d is configured by winding a conductive wire 15 on the coil support member 14.

Furthermore, a power supply device 16 supplying electrical power to the lower coil 13d (energization) is connected to the lower coil 13d (refer to FIGS. 1, 2A, and 2B).

The number of the coils, the diameter of the conductive wire 15, or the number of windings of the conductive wire 15 is appropriately determined in accordance with, for example, the lengths of the target 3, the distance between the target 3 and the substrate W, the rated current of the power supply devices 16, or the intensity (gauss) of the magnetic field to be generated.

The power supply devices 16 have a known structure including a control circuit (not shown in the figure) that can optionally modulate the current value and the direction of the current to be supplied to each of the upper coil 13u and the lower coil 13d.

In the embodiment, the current value and the direction of the current to be supplied to each of the upper coil 13u and the lower coil 13d are selected so that a magnetic field is generated in each of the upper coil 13u and the lower coil 13d due to energization and so that the synthetic magnetic field in which the magnetic fields are combined forms a perpendicular magnetic field in the inner space of the vacuum chamber 2 (for example, the coil current is 15A, the perpendicular magnetic field in the inner space is 100 gauss).

Particularly, in the embodiment, the constitution is described in which a separate power supply device 16 is provided at each of the upper coil 13u and the lower coil 13d in order to optionally change the current value and the direction of the current to be supplied to each of the upper coil 13u and the lower coil 13d.

The invention is not limited to this configuration.

In the case of supplying electrical power to each of the coils 13u and 13d by the same current values in the same directions of the currents, a constitution in which the electrical power is supplied to each of the coils 13u and 13d by use of one power supply device may be adopted.

Additionally, the film formation apparatus 1 of the embodiment can control the electrical currents which are to be applied to the coils 13u and 13d such that the value of the current which is to be applied to the upper coil 13u is different from the value of the current which is to be applied to the lower coil 13d.

FIGS. 2A and 2B show perpendicular magnetic field lines M (M1, M2) passing (through) between the entire surface of the target 3 and the entire surface of the substrate W.

In FIGS. 2A and 2B, the magnetic field lines M1 and M2 is indicated by arrows, the arrows are illustrated for convenience and explanation, and the arrows do not limit the directions of magnetic fields.

That is, the magnetic field lines M1 and M2 include both a direction from North polarity toward South polarity in the magnet and a direction from South polarity toward North polarity in the magnet.

FIG. 2A shows the magnetic field lines M1 when the value of the current which is applied to the upper coil 13u is the same as the value of the current which is applied to the lower coil 13d.

The current values are controlled by applying the same current values to each coil so that the density of magnetic flux which is generated at the position close to the target 3 (magnetic flux density near the target 3) and the density of magnetic flux which is generated at the position close to the substrate W (magnetic flux density near the substrate W) become uniform.

On the other hand, FIG. 2B shows the magnetic field lines M2 when the value of the current which is applied to the upper coil 13u is different from the value of the current which is applied to the lower coil 13d.

Particularly, in FIG. 2B, the electrical current (Iu) is applied to the upper coil 13u which is disposed at the position close to the target 3 so that the electrical current (Iu) is greater than the electrical current (Id) to be applied to the lower coil 13d which is disposed at the position close to the substrate W.

Because of this, the magnetic field inside the vacuum chamber 2 is controlled so that the density of magnetic flux near the target 3 is greater than the density of magnetic flux near the substrate W.

Moreover, the magnetic field inside the vacuum chamber 2 is controlled so as to satisfy the relational expression 1<Iu/Id≦3 in the relationship between the current (Id) and the current (Iu).

That is, the magnitude of Iu is greater than or equal to three times the magnitude of Id.

In the film formation apparatus 1 including the above-described constitution, in the case where the sputtered particles scattered from the target 3 when the target 3 is sputtered have positive electrical charge, the scattering directions of the sputtered particles are changed according to the perpendicular magnetic field that is directed from the target 3 toward the substrate W.

For this reason, the sputtered particles are substantially perpendicularly directed to the substrate W and adhered to the entire surface of the substrate W.

Particularly, due to applying the electrical current to the upper coil 13u such that the electrical current is greater than the electrical current that is supplied to the lower coil 13d as shown in FIG. 2B, it is possible to form a predetermined thin film L with excellent coatability in the microscopic holes and trenches H having a high-aspect ratio on the entire surface of the substrate W.

Furthermore, the problem in that asymmetric coverage is formed on the peripheral portion of the substrate W is solved.

Particularly, the problem is solved in that the shape of the coat formed between the bottom of the microscopic holes and one of the side walls thereof is different from the shape of the coat formed between the bottom of the microscopic holes and the other of the side walls thereof in the cross-sectional face of the microscopic holes formed at the peripheral portion of the substrate W.

Therefore, a uniformity in the thickness of a film which is formed on the inside surface (exposed surface) of the microscopic holes is improved.

In the foregoing film formation apparatus 1 of the embodiment, the first magnetic field generation section 4 which determines the region of the target 3 to be preferentially sputtered is not changed, the scattering directions in which of the sputtered particles are scattered are changed according to the magnetic fields that are generated by each of the coils 13u and 13d of the second magnetic field generation section 13.

Because of this, it is possible to decrease the cost of manufacturing the film formation apparatus or the running cost of the film formation apparatus while the utilization efficiency of the target 3 is not degraded and a plurality of cathode units such as the above-described conventional technique are not used.

Additionally, in the film formation apparatus 1, since the upper coil 13u and the lower coil 13d are only provided outside the vacuum chamber 2, the constitution of the apparatus of the embodiment is extremely simple compared with the case such that the constitution of the apparatus is modified to use a plurality of cathode units, and the apparatus of the embodiment can be realized by modifying an existing apparatus.

Next, a film forming method using the above-described film formation apparatus 1 and a coat formed by this method will be described.

Firstly, a Si wafer is prepared as a substrate W on which a coat is to be formed.

A silicon oxide film I is formed on the top face of this Si wafer, and microscopic holes and trenches H used for wiring are formed in this silicon oxide film I by patterning in advance using a known method.

Subsequently, the case of forming a Cu film L serving as a seed layer on the Si wafer by sputtering using the film formation apparatus 1 will be described.

At first, the pressure inside the vacuum chamber 2 is reduced by activating the vacuum pumping section 12 so as to reach a predetermined vacuum degree (for example, 10⁻⁵ Pa order).

Next, a substrate W (Si wafer) is mounted on the stage 10, simultaneously, electrical power is provided to the upper coil 13u and the lower coil 13d by activating the power supply devices 16, and the perpendicular magnetic field lines M are thereby generated between the entire surface of the target 3 and the entire surface of the substrate W.

Consequently, after the pressure inside the vacuum chamber 2 reaches a predetermined value, a predetermined negative electrical potential is applied (supplying electrical power) from the DC power source 9 to the target 3 while introducing argon gas or the like (sputter gas) into the inside of the vacuum chamber 2 at a predetermined flow rate.

For this reason, plasma atmosphere is generated in the vacuum chamber 2.

In this case, due to the magnetic field which is generated by the first magnetic field generation section 4, ionized electrons and secondary electrons generated by sputtering are captured in the space (anterior space) to which the sputtering face 3a is exposed, and plasma is generated in the space to which the sputtering face 3a is exposed.

Noble gas ions such as argon ions or the like in plasma collide with sputtering face 3a, the sputtering face 3a is thereby sputtered, and Cu atoms or Cu ions scatter from the sputtering face 3a toward the substrate W.

At this time, particularly, the directions in which Cu having positive electrical charge are scattered are converted into the direction vertical to the substrate W by the perpendicular magnetic field, and the sputtered particles are thereby substantially perpendicularly directed to the substrate W and adhered to the entire surface of the substrate W.

Because of this, the film is formed in the microscopic holes and trenches H on the entire surface of the substrate W with excellent coatability.

Additionally, the apparatus is described in the embodiment which allows the perpendicular magnetic field to be generated by providing electrical power to the upper coil 13u and the lower coil 13d, however, the invention is not limited to the apparatus constitution as long as the apparatus is capable of allowing the perpendicular magnetic field lines M to be generated between the entire surface of the target 3 and the entire surface of the substrate W.

The perpendicular magnetic field may be generated inside vacuum chamber by appropriately arranging, for example, a known sintered magnet at the internal side or the outer side of the vacuum chamber.

### EXAMPLES

Next, Examples of a film formation apparatus and a film forming method of the invention will be described.

In this Example, a Cu coat was formed on the substrate W by use of the film formation apparatus 1 shown in FIG. 1.

Specifically, the substrate W was prepared such that a silicon oxide film was formed over the entirety of the top face of a Si wafer of φ300 mm and microscopic trenches (the width thereof is 40 nm and the depth thereof is 140 nm) was formed on this silicon oxide film by patterning using a known method.

In addition, as a target, the target was used which is manufactured so that the compositional ratio of Cu is 99% and the diameter of the sputtering face is φ400 mm

The distance between the target and the substrate was determined to be 400 mm, and the distance between the lower edge of the upper coil 13u and the target 3 and the distance between the upper edge of the lower coil 13d and the substrate W were determined to be 50 mm, respectively.

Furthermore, regarding a film formation condition, Ar was used as a sputter gas and the gas was introduced into the vacuum chamber at the flow rate of 15 sccm.

Moreover, the supply electrical power which is to be supplied to the target was 18 kW (electrical current of 30 A).

As the values of the currents which are supplied to the coils 13u and 13d, current values having negative polarity were applied thereto so that a downward perpendicular magnetic field is generated inside the vacuum chamber.

Additionally, each value of the current that is supplied to the coils 13u and 13d was varied in the range of −5 A to −40 A in order to evaluate the changes in coatability due to the fact that the current values are varied.

Consequently, the length of time for sputtering was ten seconds, and the Cu film was formed on the substrate W on which the microscopic trenches are formed.

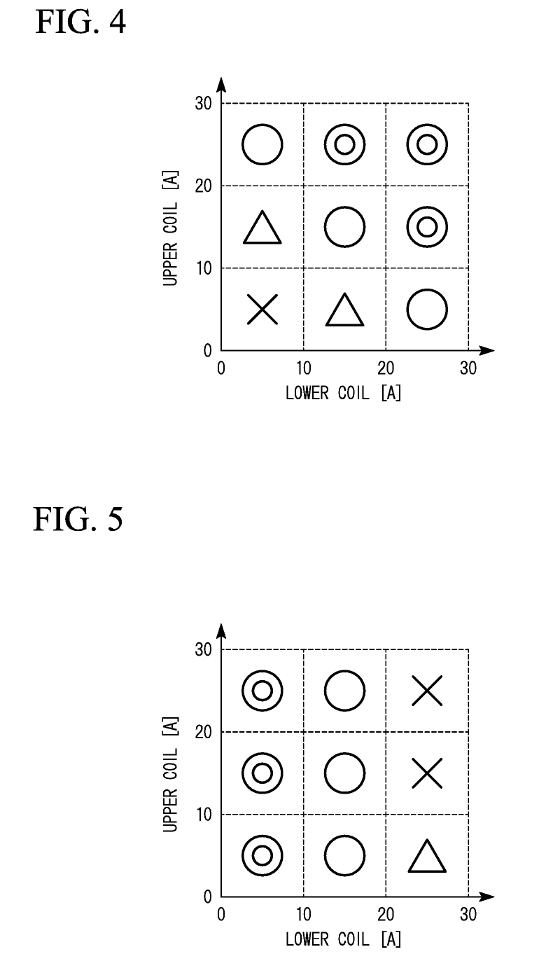

Particularly, the current values shown in the following explanation and FIGS. 4 and 5 are represented using absolute value.

As described above, the values of the currents that are supplied to the coils 13u and 13d were varied, the Cu film was formed on the substrate W, and the formed Cu film was evaluated.

The evaluation standards (evaluation items) were a coatability of the Cu film formed on the side wall of the microscopic trench, a minimum opening of the microscopic trench after the Cu film were formed, and a bottom coverage (the ratio of the film thickness of the Cu film formed on the bottom portion of the microscopic trench to the film thickness of the Cu film formed on the peripheral surface of the microscopic hole).

FIG. 3 is a cross-sectional view schematically showing the microscopic trench in which the Cu film is formed with a high-aspect ratio.

Firstly, the coatability of the Cu film which is formed on the side wall of the microscopic trench at the peripheral portion of the substrate W was evaluated.

FIG. 4 shows the evaluation result of the coatability of the Cu film by observing the Cu film which is formed on the side wall of the microscopic trench in the case where the value of the current which is applied to each of the coils 13u and 13d was changed.

In FIG. 4, the axis of abscissas represents the value of the current which is supplied to the lower coil and the axis of ordinate represents the value of the current which is supplied to the upper coil.

In FIG. 4, the “⊚” means that the coverage of the Cu film formed on the side wall of the microscopic trench was greater than or equal to 60%, this means that sufficient film thickness was obtained, that is, an excellent evaluation result.

Furthermore, the “◯” means that the coverage of the Cu film formed on the side wall of the microscopic trench was in the range of 40% to 60%.

Additionally, the “Δ” means that the coverage of the Cu film formed on the side wall of the microscopic trench was in the range of 20% to 40%.

Moreover, the “×” means that the coverage of the Cu film formed on the side wall of the microscopic trench was less than or equal to 20%.

According to the above results, it was found that the Cu film can be formed on the side wall of the microscopic trench with sufficient film thickness in the case where the value of the current supplied to one of the coils 13u and 13d is greater than or equal to 25 A or the values of the currents supplied to both the coils 13u and 13d are greater than or equal to 15 A.

Furthermore, in the case where the values of the current supplied to both the coils are greater than or equal to 15 A, particularly, the values of the current supplied to both the coils are 25 A, the condition of the formed Cu film was excellent. Regarding the coatability of the Cu film formed on the side wall of the microscopic trench, it was found that, the higher the current value, the more excellent coatability can be obtained.

Subsequently, a minimum opening of the microscopic trench after the Cu film was formed was evaluated.

The minimum opening means the diameter D of the opening portion of the microscopic hole H after the Cu film was formed (refer to FIG. 3).

FIG. 5 shows the evaluation result of the minimum opening D after the Cu film was formed in the case where the value of the current which is applied to each of the coils 13u and 13d was changed.

In FIG. 5, the axis of abscissas represents the value of the current which is supplied to the lower coil and the axis of ordinate represents the value of the current which is supplied to the upper coil.

In FIG. 5, the “⊚” means that a sufficient minimum opening was obtained such that the diameter thereof was greater than or equal to 30 nm, that is, an excellent evaluation result.

Furthermore, the “◯” means that a minimum opening was obtained such that the diameter thereof was greater than or equal to 20 nm.

The “Δ” means that the diameter of the minimum opening was less than or equal to 10 nm.

The “×” means that an opening was not formed.

According to the above results, it was found that, when the value of the current supplied to the lower coil 13d was less than or equal to 15 A, a minimum opening satisfying the standard, that is, a sufficient minimum opening D having the diameter of 30 nm or more was formed.

Particularly, in the case where the value of the current supplied to the lower coil 13d was 5 A, an excellent result was obtained.

Additionally, as shown in FIG. 5, it was found that an excellent evaluation result was obtained in the case where the currents are controlled so as to satisfy the relational expression 1<Iu/Id≦3 in the relationship between the current (Id) supplied to the lower coil 13d and the current (Iu) supplied to the upper coil 13u.

Next, a bottom coverage was evaluated by calculating the bottom coverage based on the film thickness of the Cu film formed on the bottom portion of the microscopic trench and the film thickness of the Cu film formed on the peripheral surface of the microscopic hole.

In this evaluation, both the evaluation result of Cu agglomeration and the evaluation result of the minimum opening of the microscopic trench satisfy the standard. Particularly, the bottom coverage was calculated under the conditions in which an excellent result was obtained in the evaluation of Cu agglomeration.

Both results of Cu agglomeration and the minimum opening were excellent under the conditions in which the values of the currents supplied to the upper coil and the lower coil were 15 A and 15 A and under the conditions in which the values were 25 A and 15 A.

Consequently, regarding the film thickness of the Cu film on the bottom portion of the microscopic trench and the Cu film on the peripheral surface of the microscopic hole, which were formed under such conditions, the bottom coverage thereof was calculated.

The thickness Ta of the film formed on the peripheral surface of the microscopic hole and the thickness Tb of the film formed on the bottom surface of the microscopic hole as shown in FIG. 3 were measured, and the value in which the thickness of Tb is divided by the thickness of Ta, that is, a bottom coverage (Tb/Ta) was calculated.

TABLE 1

| | | | BOTTOM COVERAGE (Tb/Ta) | | |
|---|---|---|---|---|---|
| | CURRENT | | CENTER | END OF | END OF |
| | VALUE (A) | | OF | BOTTOM | BOTTOM |
| | Iu | Id | BOTTOM | SURFACE | SURFACE |
| | (UPPER | (LOWER | SURFACE | 1 | 2 |
| | COIL) | COIL) | (Tb(1)/Ta) | (Tb(2)/Ta) | (Tb(3)/Ta) |
| CONDITION 1 | −25 | −15 | 87.8% | 78.0% | 68.3% |
| CONDITION 2 | −15 | −15 | 75.6% | 73.0% | 61.8% |

Table 1 shows a result of the bottom coverage being calculated.

Table 1 shows a calculation result of the bottom coverages of the center portion of the substrate W (a region of a radius of 20 mm from the substrate center portion) and the peripheral portion of the substrate W (an outer region of the substrate (peripheral portion) separated by a distance of 130 mm from the substrate center).

The bottom coverage (Tb(1)/Ta) of the center portion of the bottom of the microscopic hole was measured on the center portion of the substrate W.

On the other hand, it is believed that the sputtered particles are incident to the peripheral portion of the substrate W at an inclined angle and adhered thereto. Therefore, the bottom coverages (Tb(2)/Ta and Tb(3)/Ta) of both ends of the bottom of the microscopic holes were measured.

As shown in Table 1, the percentage of the bottom coverage in the case where the values of the current supplied to the upper coil and the lower coil were 25 A and 15 A, respectively (condition 1), was greater than the percentage of the bottom coverage in the case where the values of the current supplied to the upper coil and the lower coil were 15 A and 15 A, respectively (condition 2).

As a result, it was found that the magnetic flux density near the target becomes greater than the magnetic flux density near the body to be processed by making the value of the current supplied to the upper coil greater than the value of the current supplied to the lower coil as shown in FIG. 2B, the bottom coverage is improved because the sputtered particles scattering near the target are effectively induced toward the body to be processed (substrate W).

According to the above-described results, it was found that the Cu film which is formed on the substrate W under the conditions in which the values of the currents supplied to the upper coil and the lower coil were 25 A was 15 A, respectively, was an excellent film in terms of evaluations of the coatability of the Cu film formed on the side wall of the microscopic trench, the minimum opening of the microscopic trench after the Cu film was formed, and the bottom coverage thereof.

### INDUSTRIAL APPLICABILITY

The invention is widely applicable to a film formation apparatus and a film forming method which are used for forming a coat on a surface of a body to be processed, particularly, applicable to a film formation apparatus and a film forming method employing a DC magnetron method using a sputtering method which is one of several thin film forming methods.

What is claimed is:

1. A film formation apparatus comprising:
a chamber having an inner space in which both a body to be processed and a target are disposed so that the body to be processed and the target are opposed to each other, the body to be processed having a film formation face, the target having a sputtering face;
a pumping section reducing a pressure inside the chamber;
a first magnetic field generation section generating a magnetic field in the inner space to which the sputtering face is exposed;
a direct-current power source applying a negative direct electric current voltage to the target;
a gas introduction section introducing a sputter gas into the chamber; and
a second magnetic field generation section including a first generation portion to which a current defined as “Iu” is applied and a second generation portion to which a current defined as “Id” is applied, the first generation portion being disposed at a position close to the target, the second generation portion being disposed at a position close to the body to be processed, the second magnetic field generation section applying the currents to the first generation portion and the second generation portion so as to satisfy relational expression Id<Iu, the second magnetic field generation section generating a perpendicular magnetic field so as to allow perpendicular magnetic lines of force thereof having a predetermined distance to pass between an entire surface of the sputtering face and an entire surface of the film formation face of the body to be processed.

2. The film formation apparatus according to claim 1, wherein the Iu and the Id satisfy relational expression 1<Iu/Id≦3.

3. A film forming method comprising:
preparing a film formation apparatus, the film formation apparatus comprising:
a chamber having an inner space in which both a body to be processed and a target are disposed so that the body to be processed and the target are opposed to each other, the body to be processed having a film formation face, the target having a sputtering face;
a pumping section reducing a pressure inside the chamber; a first magnetic field generation section generating a magnetic field in the inner space to which the sputtering face is exposed;
a direct-current power source applying a negative direct electric current voltage to the target;
a gas introduction section introducing a sputter gas into the chamber; and a second magnetic field generation section including a first generation portion disposed at a position close to the target and a second generation portion disposed at a position close to the body to be processed, the second magnetic field generation section generating a perpendicular magnetic field so as to allow perpendicular magnetic lines of force thereof having a predetermined distance to pass between an entire surface of the sputtering face and an entire surface of the film formation face of the body to be processed;
applying a current defined as “Iu” to the first generation portion;
applying a current defined as “Id” to the second generation portion; and
controlling the currents which are applied to the first generation portion and the second generation portion so as to satisfy relational expression Id<Iu.

4. The film forming method according to claim 3, wherein the currents supplied to the first generation portion and the second generation portion are controlled so that the Iu and the Id satisfy relational expression 1<Iu/Id≦3.
